(19) United States
(12) Patent Application Publication
(10) Pub. No.: US 2015/0027761 A1
(43) Pub. Date: Jan. 29, 2015

(54) PRINTED CIRCUIT BOARD AND METHOD OF MANUFACTURING THE SAME

(71) Applicant: SAMSUNG DISPLAY CO., LTD., YONGIN-CITY (KR)

(72) Inventors: Hyuk-Hwan KIM, Gyeonggi-do (KR); Young-Jun SEO, Seoul (KR); Jung-Kyun KIM, Seoul (KR); Seok-Hyun NAM, Seoul (KR)

(21) Appl. No.: 14/333,639

(22) Filed: Jul. 17, 2014

(30) Foreign Application Priority Data
Jul. 23, 2013 (KR) 10-2013-0086509

(51) Int. Cl. H05K 3/18; H05K 1/02

(52) U.S. Cl. CPC H05K 3/188; H05K 1/0296; H05K 2201/032; H05K 2203/0723
USPC 174/257; 205/125; 205/126

(57) ABSTRACT

A printed circuit board includes a first seed layer, a second seed layer, and a metal layer. The first and second seed layers are disposed on a base substrate and spaced apart from each other. The metal layer covers the first and second seed layers except a first side of the first seed layer and a second side of the second seed layer. The first side of the first seed layer faces the second side of the second seed layer.

### CROSS-REFERENCE TO RELATED APPLICATION

This application claims priority under 35 U.S.C. §119 to Korean Patent Application No. 10-2013-0086509, filed on Jul. 23, 2013 in the Korean Intellectual Property Office (KIPO), the disclosure of which is incorporated herein by reference in its entirety.

### TECHNICAL FIELD

The present invention relates to a printed circuit board and a method of manufacturing a printed circuit board.

### DISCUSSION OF RELATED ART

Printed circuit boards include various electronic components and metal wirings to route electrical signals among the electronic components. In manufacturing printed circuit boards, metal patterns are formed on a base substrate.

### SUMMARY

According to an exemplary embodiment of the present invention, a printed circuit board includes a first seed layer, a second seed layer, and a metal layer. The first and second seed layers are disposed on a base substrate and spaced apart from each other. The metal layer covers the first and second seed layers except a first side of the first seed layer and a second side of the second seed layer. The first side of the first seed layer faces the second side of the second seed layer.

According to an exemplary embodiment of the present invention, a method of manufacturing a printed circuit hoard is provided. A mask pattern is formed on a base substrate. A first seed layer and a second seed layer are formed on the base substrate. The first seed layer is spaced apart from the second seed layer. The first seed layer covers a first corner of the mask pattern and the second seed layer covers a second corner of the mask pattern. A metal layer is selectively formed on the first and second seed layers. The mask pattern is removed from the base substrate, thereby exposing the base substrate underlying the mask pattern.

According to an exemplary embodiment of the present invention, a method of manufacturing a printed circuit board is provided. A first seed layer and a second seed layer are formed on a base substrate. The first seed layer is spaced apart from the second seed layer. An active portion is formed on the base substrate disposed between the first seed layer and the second seed layer, a portion of the first seed layer and a portion of the second seed layer. A metal layer is selectively formed on the first and second seed layers and the active portion. A portion of the metal layer disposed on the active pattern is removed to expose the active pattern.

### BRIEF DESCRIPTION OF THE DRAWINGS

These and other features of the present invention will become more apparent by describing in detail exemplary embodiments thereof with reference to the accompanying drawings of which:

FIGS. 1 and 2 are cross-sectional views illustrating a method of manufacturing a printed circuit board in accordance with an exemplary embodiment of the present invention;

FIG. 3 is a plan view illustrating a method of manufacturing a printed circuit board in accordance with an exemplary embodiment of the present invention;

FIG. 4 is a cross-sectional view taken along the line I-I′ in FIG. 3;

FIG. 5 is a cross-sectional view taken along the line A-A′ in FIG. 3;

FIG. 6 is a cross-sectional view illustrating a printed circuit board in accordance with an exemplary embodiment of the present invention;

FIGS. 7 and 8 are cross-sectional views illustrating a method of manufacturing a printed circuit board in accordance with an exemplary embodiment of the present invention;

FIG. 9 is a plan view illustrating a method of manufacturing a printed circuit board in accordance with another example embodiment of the present invention;

FIG. 10 is a cross-sectional view taken along the line II-II′ in FIG. 9;

FIG. 11 is a cross-sectional view taken along the line B-B′ in FIG. 9;

FIG. 12 is a cross-sectional view illustrating a printed circuit board according to the exemplary embodiment of the present invention in FIG. 7;

FIGS. 13 and 14 are cross-sectional views illustrating a method of manufacturing a printed circuit board in accordance with still another exemplary embodiment of the present invention;

FIG. 15 is a plan view illustrating a method of manufacturing a printed circuit board in accordance with the exemplary embodiment of the present invention in FIG. 13;

FIG. 16 is a cross-sectional view taken along the line III-III′ of FIG. 15;

FIG. 17 is a cross-sectional view taken along the line C-C′ of FIG. 15; and

FIG. 18 is a cross-sectional view illustrating a printed circuit board in accordance with an exemplary embodiment of the present invention.

### DETAILED DESCRIPTION OF THE EXEMPLARY EMBODIMENTS

Exemplary embodiments of the present invention will be described below in detail with reference to the accompanying drawings. However, the present invention may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

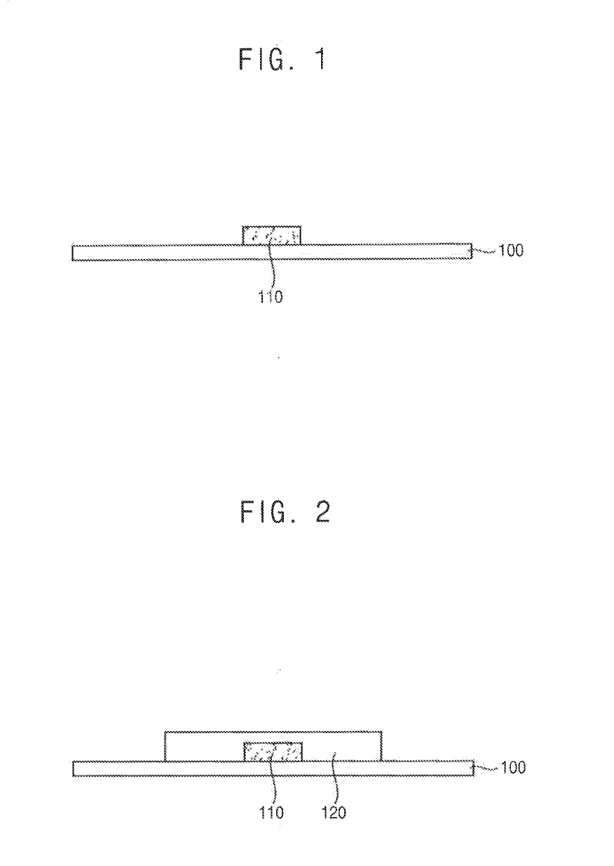

FIGS. 1 to 6 are views illustrating a method of manufacturing a printed circuit board in accordance with an exemplary embodiment of the present invention. FIGS. 1 and 2 are cross-sectional views illustrating a method of manufacturing a printed circuit board in accordance with an exemplary embodiment of the present invention.

Referring to FIG. 1, a mask pattern 110 is formed on a base substrate 100. The base substrate 100 may include a substrate such as a prepreg having a thermosetting resin such as an epoxy resin. The epoxy resin is heat-resistant, and adhesive.

The mask pattern 110 is formed in a region between metal wirings spaced apart from each other. The mask pattern 110 may include a photosensitive resin or a thermosetting resin. For example, the mask pattern 110 may include, but is not limited to, diazo resin, azide resin, polyvinyl alcohol resin, acrylic resin, polyamide resin, polyester, polyethylene resin, polypropylene resin or polyvinyl chloride resin.

The mask pattern 110 is formed by a screen printing process. The mask pattern 110 is less than about 1 μm (micrometer) in thickness. The position, shape and size of the mask pattern 110 are not limited to thereto, and they may be various depending on the design for metal wirings of the printed circuit board.

Referring to FIG. 2, a seed layer 120 is formed on the base substrate 100 to cover the mask pattern 110. The seed layer 120 overlaps with at least a portion of the mask pattern 110.

The seed layer 120 may be formed of a metal paste including, but is not limited to, a metal powder, an ultraviolet curable resin or a thermosetting resin. For example, the metal paste may include silver (Ag), titanium (Ti), chromium (Cr), nickel (Ni), aluminum (Al), gold (Au), platinum (Pt), tungsten (W), copper (Cu) or molybdenum (Mo). For example, the seed layer 120 is formed of a metal paste including silver by a screen printing process, having the thickness of about 0.5 μm˜about 5 μm. The position, shape and size of the mask pattern 110 are not limited to thereto, and they may be various depending on the design for metal wirings of the printed circuit board.

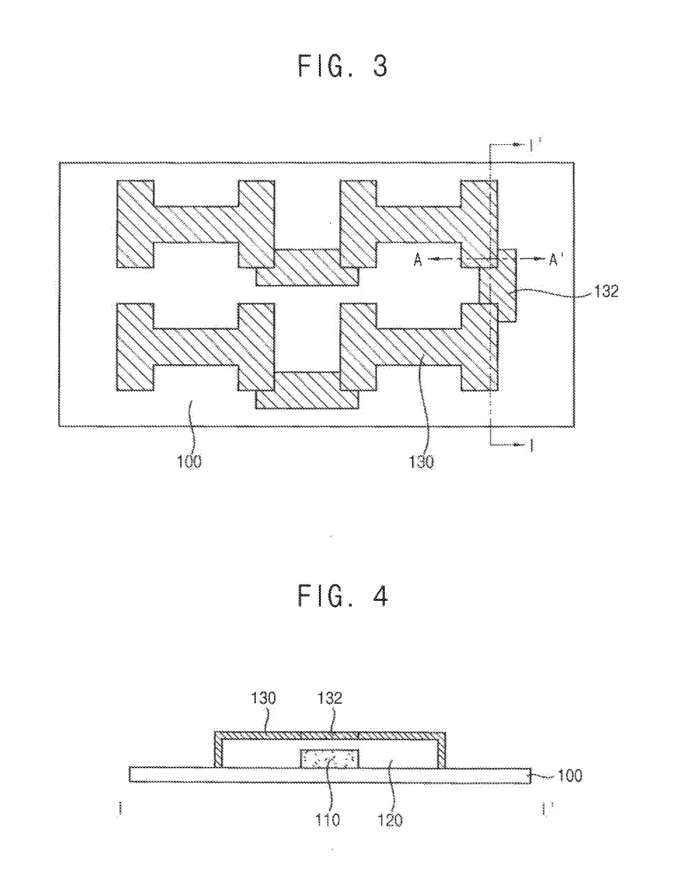

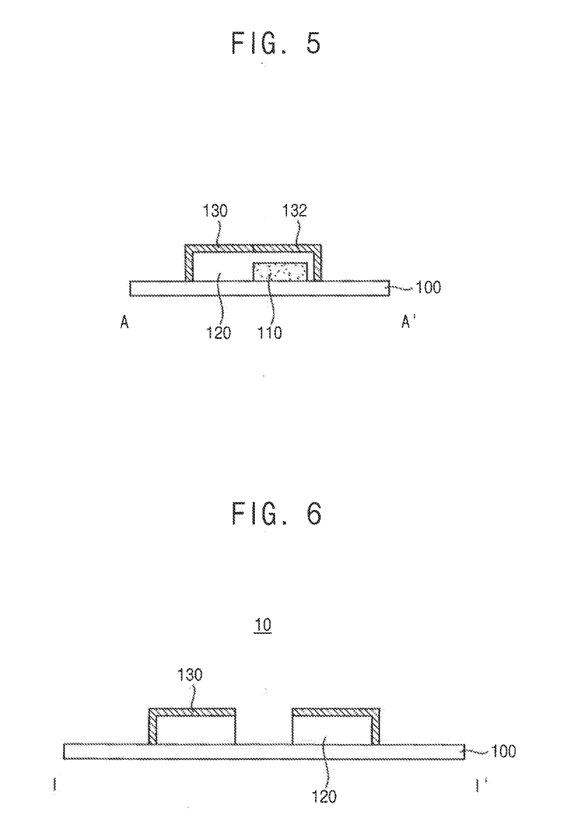

FIG. 3 is a plan view illustrating a method of manufacturing a printed circuit board in accordance with an exemplary embodiment of the present invention. FIG. 4 is a cross-sectional view taken along the line I-I′ in FIG. 3. FIG. 5 is a cross-sectional view taken along the line A-A′ in FIG. 3.

Referring to FIGS. 3 to 5, a metal layer 130 is formed on the seed layer 120. The metal layer 130 covers the entire surface of the seed layer 120. The seed layer 120 may include a metal material different from the metal layer 130.

For example, the metal layer 130 may include silver (Ag), titanium (Ti), chromium (Cr), nickel (Ni), aluminum (Al), aluminum (Al), gold (Au), platinum (Pt), tungsten (W), copper (Cu) or molybdenum (Mo). For example, the metal layer 130 is formed of copper.

The metal layer 130 is formed using an electroplating process. The electroplating is a method in which anode, cathode and electrolyte are used to form a desired metal on the cathode. The base substrate including the seed layer 120 is dipped in a copper sulfate solution (CuSO₄) or copper chloride solution (CuCl₂), and then, current flows through the seed layer 120 such that the surface of the seed layer 120 is electroplated to form the metal layer 130 on the seed layer 120. The thickness of the metal layer 130 is about 10 μm˜about 40 μm.

FIG. 6 is a cross-sectional view illustrating a printed circuit board in accordance with an exemplary embodiment of the present invention.

Referring to FIG. 6, the mask pattern 110 of FIG. 5 is removed to form a printed circuit board 10 having wirings formed on the base substrate 100.

If the mask pattern 110, the seed layer 120 and a subsidiary metal layer 132 disposed on the mask pattern 110 are not removed, the metal wirings are electrically connected to each other by the subsidiary metal layer 132 so that the printed circuit board does not work. The subsidiary metal layer 132 is a portion of the metal layer 130 on the mask pattern 110. Accordingly, the mask pattern 110, the seed layer 120 and the subsidiary metal layer 132 disposed on the mask pattern 110 are removed from the base substrate 100. An exposed portion of the mask pattern 110 may be removed from the base substrate 100 using an organic solvent.

For example, the organic solvent may include, but is not limited to, benzene, toluene, xylene, methyl acetate, ethyl acetate, butyl acetate, isobutyl acetate, pentyl acetate, isopentyl acetate, acetone, methylethylketone, methylbutylketone or methylisobutylketone. For example, the organic solvent includes acetone.

The mask pattern 110, the seed layer 120 and the subsidiary metal layer 132 disposed on the mask pattern 110 are removed from the base substrate 100 to form metal wirings spaced apart from each other.

Alternatively, the mask pattern 110, the seed layer 120 and the subsidiary metal layer 132 disposed on the mask pattern 110 may be removed from the base substrate 100 using a cleaning water of about 70° C.˜about 90° C.

Further, a portion of the mask pattern 110 exposed by the seed layer 120 may extend in a direction.

The printed circuit board 10 includes the seed layer 120 disposed on the base substrate 100 and the metal layer 130 on the seed layer 120 to cover a side of the seed layer 120 and expose another side of the seed layer 120.

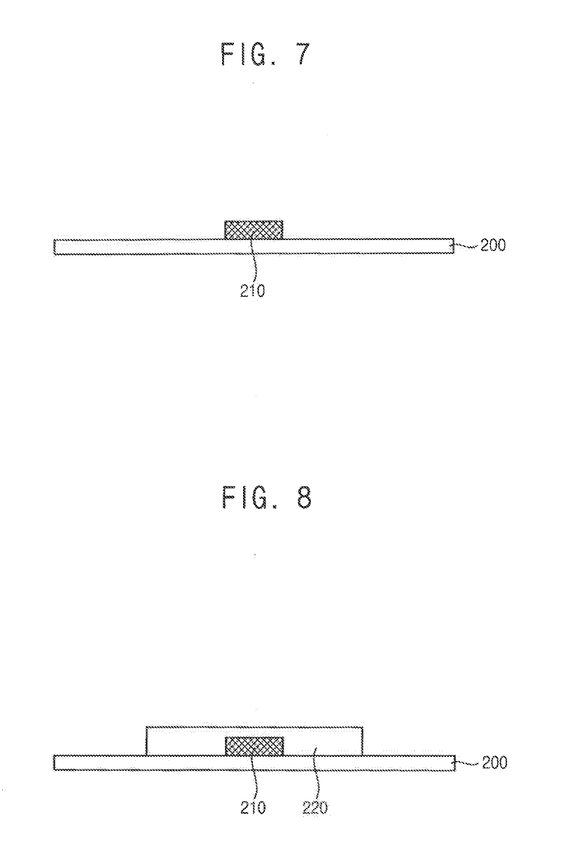

FIGS. 7 to 12 are views illustrating a method of manufacturing a printed circuit board in accordance with another exemplary embodiment of the present invention. FIGS. 7 and 8 are cross-sectional views illustrating a method of manufacturing a printed circuit board in accordance with an exemplary embodiment of the present invention.

Referring to FIG. 7, a mask pattern 210 is formed on a base substrate 200. The base substrate 200 may includes a prepreg having a thermosetting resin such as an epoxy resin to increase a heat resisting property and an adhesive strength therebetween.

The mask pattern 210 is formed in a region between metal wirings, which will be formed later, spaced apart from each other. The mask pattern 210 may include a photosensitive resin or a thermosetting resin used for forming a photoresist. For example, the mask pattern 210 may include, but is not limited to, diazo resin, azide resin, polyvinyl alcohol resin, acrylic resin, polyamide resin, polyester, polyethylene resin, polypropylene resin or polyvinyl chloride resin.

The mask pattern 210 is formed as a tape shape. For example, the mask pattern 210 is less than about 10 μm in thickness. The position, shape and size of the mask pattern 110 are not limited to thereto, and they may be various depending on the design for metal wirings of the printed circuit board.

Referring to FIG. 8, a seed layer 220 is formed on the base substrate 200 to cover the mask pattern 210. The seed layer 220 overlaps at least a portion of the mask pattern 210.

The seed layer 220 may be formed of a metal paste including a metal powder, an ultraviolet curable resin or a thermosetting resin. For example, the metal paste may include silver (Ag), titanium (Ti), chromium (Cr), nickel (Ni), aluminum (Al), gold (Au), platinum (Pt), tungsten (W), copper (Cu) or molybdenum (Mo). For example, the seed layer 220 is formed using a metal paste including silver, having the thickness of about 0.5 μm˜about 5 μm. The position, shape and size of the mask pattern 110 are not limited to thereto, and they may be various depending on the design for metal wirings of the printed circuit hoard.

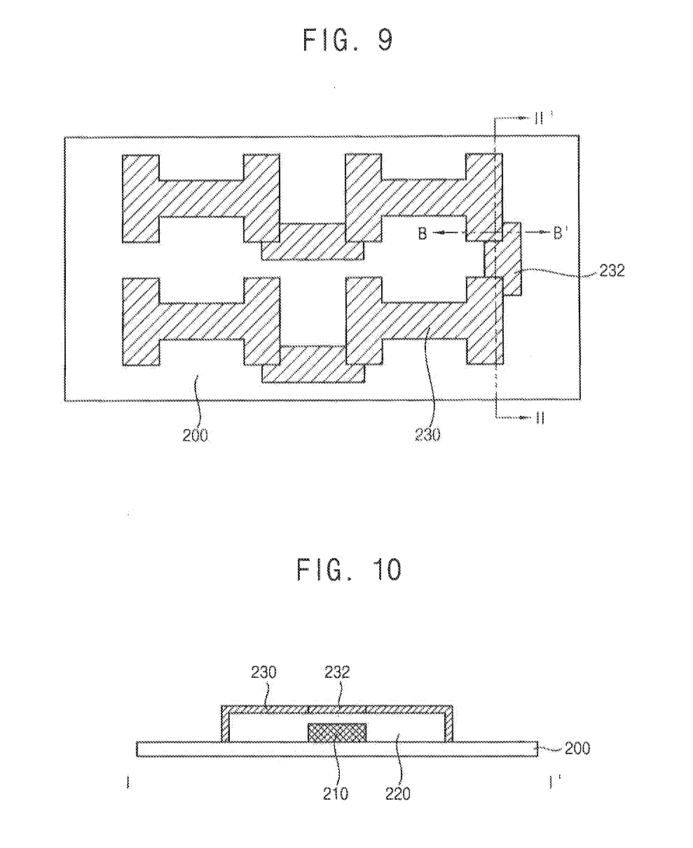

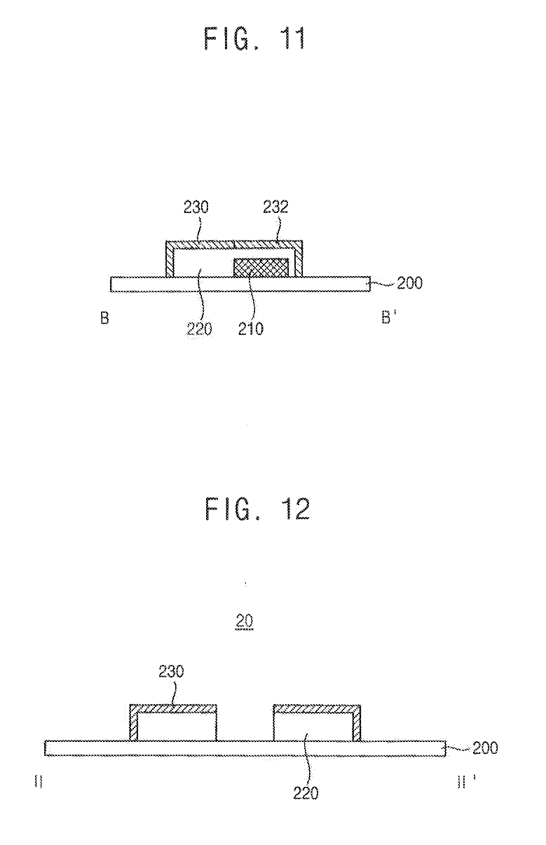

FIG. 9 is a plan view illustrating a method of manufacturing a printed circuit board in accordance with another example embodiment of the present invention. FIG. 10 is a cross-sectional view taken along the line II-II′ of FIG. 9. FIG. 11 is a cross-sectional view taken along the line B-B′ of FIG. 9.

Referring to FIGS. 9 to 11, a metal layer 230 is formed on the seed layer 220. The metal layer 230 covers the entire surface of the seed layer 220. The seed layer 220 may include a metal material different from the metal layer 230.

For example, the metal layer 230 may include silver (Ag), titanium (Ti), chromium (Cr), nickel (Ni), aluminum (Al), gold (Au), platinum (Pt), tungsten (W), copper (Cu) or molybdenum (Mo). For example, the metal layer 230 may be formed of copper.

The metal layer 230 is formed using an electroplating process. The base substrate 200 including the seed layer 220 is dipped in a copper sulfate solution (CuSO₄) or copper chloride solution (CuCl₂), and then, current flows through the seed layer 220 such that the seed layer 220 is electroplated to form the metal layer 230 on the seed layer 220.

FIG. 12 is a cross-sectional view illustrating a printed circuit board according to an exemplary embodiment of the present invention.

Referring to FIG. 12, the mask pattern 210 is removed to form a printed circuit board 200.

If the mask pattern 210, the seed layer 220 and a subsidiary metal layer 232 disposed on the mask pattern 210 are not removed, the metal wirings are electrically connected to each other by the subsidiary metal layer 232 so that the printed circuit board does not work. The subsidiary metal layer 232 is a portion of the metal layer 230 on the mask pattern 210. Thus, the mask pattern 210, the seed layer 220 and the subsidiary metal layer 232 disposed on the mask pattern 210 are removed. An exposed portion of the mask pattern 210 is removed from the base substrate 200 by separating the exposed portion of the mask pattern 210 of a tape shape using tweezers or picking devices.

The mask pattern 210, the seed layer 220 and the subsidiary metal layer 232 disposed on the mask pattern 210 are removed from the base substrate 200 to form metal wirings spaced apart from each other.

Alternatively, the mask pattern 210, the seed layer 220 and the subsidiary metal layer 232 disposed on the mask pattern 210 may be removed from the base substrate 200 using a cleaning water of about 70° C.˜about 90° C.

Further, a portion of the mask pattern 210 exposed by seed layer 220 may extend in a direction in which the seed layer 220 is not formed.

The printed circuit board 20 includes the seed layer 220 disposed on the base substrate 200 and the metal layer 230 on the seed layer 220 to cover a side of the seed layer 220 and expose another side of the seed layer 220.

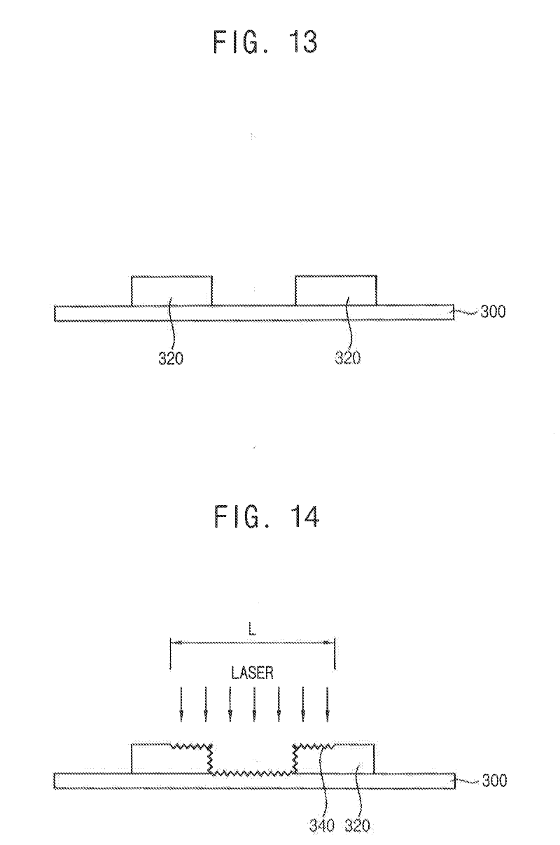

FIGS. 13 to 18 are views illustrating a method of manufacturing a printed circuit board in accordance with still another exemplary embodiment of the present invention. FIGS. 13 and 14 are cross-sectional views illustrating a method of manufacturing a printed circuit board in accordance with still another exemplary embodiment of the present invention.

Referring to FIG. 13, a base substrate 300 is provided. The base substrate 300 includes a prepreg including a thermosetting resin such as an epoxy resin to increase a heat resisting property and an adhesive strength therebetween. A seed layer 320 is formed on the base substrate 300 for electric connection.

The seed layer 320 may be formed of a metal paste including, but is not limited to, a metal powder, an ultraviolet curable resin or a thermosetting resin. For example, the metal paste may include silver (Ag), titanium (Ti), chromium (Cr), nickel (Ni), aluminum (Al), gold (Au), platinum (Pt), tungsten (W), copper (Cu) or molybdenum (Mo). For example, the seed layer 320 may be formed using a metal paste including silver by a screen printing process. A thickness of the seed layer 320 is about 0.5 μm˜about 5 μm. The position, shape and size of the mask pattern 110 are not limited to thereto, and they may be various depending on the design for metal wirings of the printed circuit board. Referring to FIG. 14, a laser beam is irradiated onto portions of the base substrate 300 and the seed layer 320 to form an active portion 340 in the seed layer 320. The active portion 340 is an area of connecting separated metal patterns. The portions L of the base substrate 300 and the seed layer 320 are irradiated by the laser beam to form the active portion 340 having a desired surface roughness. The position, shape and size of the active portion 340 are not limited to thereto, and they may be various depending on the design for metal wirings of the printed circuit board.

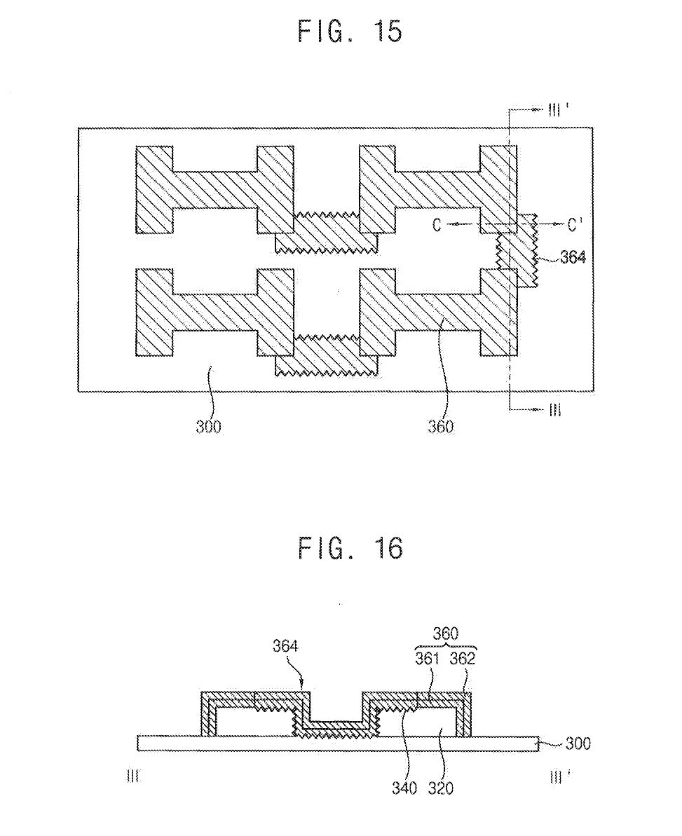

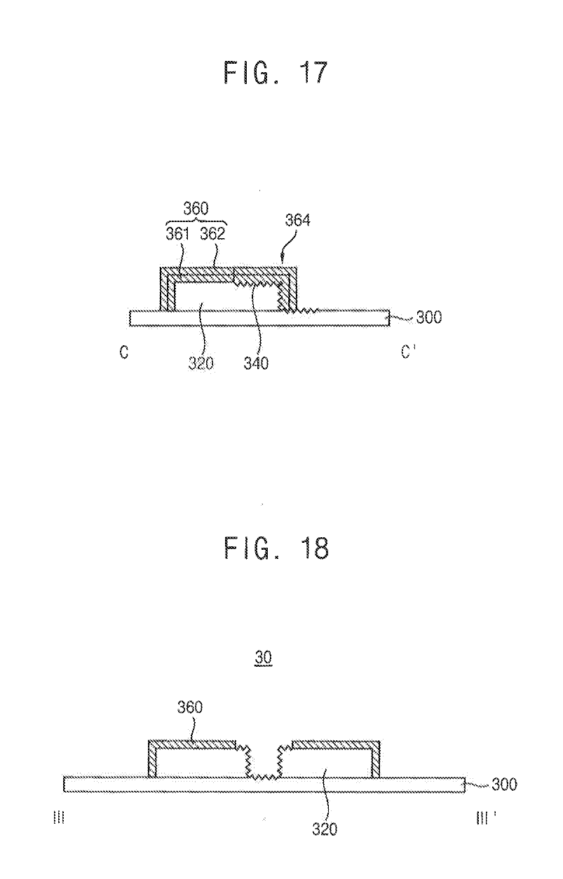

FIG. 15 is a plan view illustrating a method of manufacturing a printed circuit board in accordance with an exemplary embodiment of the present invention. FIG. 16 is a cross-sectional view taken along the line III-III′ of FIG. 15. FIG. 17 is a cross-sectional view taken along the line C-C′ of FIG. 15.

Referring to FIGS. 15 to 17, a metal layer 360 is formed on the seed layer 320 and the active portion 340. For example, the metal layer 360 may include silver (Ag), titanium (Ti), chromium (Cr), nickel (Ni), aluminum (Al), gold (Au), platinum (Pt), tungsten (W), copper (Cu) or molybdenum (Mo). For example, the metal layer 360 is formed using copper.

A first metal layer 361 and a second metal layer 362 are sequentially formed to form the metal layer 360.

The first metal layer 361 is formed using an electroless plating process. The electroless plating is a method in which electricity is not used and a metal is chemically plated using a reducing agent. The base substrate 300 having the seed layer 320 is dipped in copper sulfate solution (CuSO₄) or copper chloride solution (CuCl₂). A surface of the seed layer 320 is coated by using formalin solution as a reducing agent. Thus, the first metal layer 361 is formed. A thickness of the first metal layer 361 is less than about 5 μm.

The second metal layer 362 is formed using an electroplating process.

The base substrate 300 having the seed layer 320 and the first metal layer 361 is dipped in copper sulfate solution (CuSO₄) or copper chloride solution (CuCl₂), and then, current flows through the first metal layer 361 to form the second metal layer 362 on the first metal layer 362. A thickness of the second metal layer 362 is about 10 μm˜about 40 μm. Thus, the metal layer 360 including the first metal layer 361 and the second metal layer 362 is formed. The metal layer 360 covers the entire surface of the seed layer 320.

A subsidiary metal layer 364 formed on the active portion 340 is not completely combined with the seed layer 320.

FIG. 18 is a cross-sectional view illustrating a printed circuit board in accordance with an exemplary embodiment of the present invention.

Referring to FIG. 18, the subsidiary metal layer 364 formed on the active portion 340 is removed to form a printed circuit board 30.

If the subsidiary metal layer 364 formed on the active portion 340 is not removed, metal wirings of the printed circuit board is electrically connected to each other so that the printed circuit board does not work. The subsidiary metal layer 364 is a portion of the metal layer 360 on the active portion 340. Thus, the subsidiary metal layer 360 formed on the active portion 340 is removed. A tape having an adhesive force greater than that with the subsidiary metal layer 364 is attached to the active portion 340. The tape is removed from the active portion 340. The subsidiary metal layer 364 formed on the active portion 340 is removed from the base substrate 300.

Alternatively, the subsidiary metal layer 364 formed on the active portion 340 may be removed from the base substrate 300 using a cleaning water of about 70° C.˜about 90° C. The subsidiary metal layer 364 formed on the active portion 340 is removed by pressure of the cleaning water.

The printed circuit board 30 includes the seed layer 320 disposed on the base substrate 300 and the metal layer 360 on the seed layer 320 to cover a side of the seed layer 320 and expose another side of the seed layer 320.

According to an exemplary embodiment of the present invention, the mask pattern formed on the base substrate serves as a sub-pattern of the printed circuit pattern. Thus, a metal wiring may be formed by using an electroplating process such that a plating speed may be increased and a process time of manufacturing the metal pattern may be decreased.

According to the exemplary embodiments of the present invention, the metal wirings are formed without using a photolithography process or an etching process, Thus, a process time and a process cost of manufacturing metal wirings may be decreased.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is clamed is:

1. A printed circuit board comprising:
a first seed layer and a second seed layer disposed on a base substrate and spaced apart from each other; and
a metal layer configured to cover the first and second seed layers except a first side of the first seed layer and a second side of the second seed layer, wherein the first side of the first seed layer faces the second side of the second seed layer.

2. The printed circuit board of claim 1, wherein the seed layer is formed using a screen printing process.

3. The printed circuit board of claim 1, wherein the metal layer is formed using an electroplating process.

4. The printed circuit board of claim 1, wherein the metal layer includes silver (Ag), titanium (Ti), chromium (Cr), nickel (Ni), aluminum (Al), gold (Au), platinum (Pt), tungsten(W), copper(Cu) or molybdenum (Mo).

5. The printed circuit board of claim 1, wherein the seed layer comprises a metal paste, a photosensitive resin or a thermosetting resin.

6. The printed circuit board of claim 1, wherein the seed layer comprises a metal material different from the metal layer.

7. A method of manufacturing a printed circuit board comprising:
forming a mask pattern on a base substrate;
forming a first seed layer and a second seed layer on the base substrate, wherein the first seed layer is spaced apart from the second seed layer and the first seed layer covers a first corner of the mask pattern and the second seed layer covers a second corner of the mask pattern;
selectively forming a metal layer on the first and second seed layers; and
removing the mask pattern from the base substrate, thereby exposing the base substrate underlying the mask pattern.

8. The method of claim 7, wherein the mask pattern comprises diazo resin, azide resin, polyvinyl alcohol resin, acrylic acid resin, polyimide, polyester, polyethylene resin, polypropylene resin or polyvinyl chloride resin.

9. The method of claim 7, wherein the seed layer is formed using a screen printing process.

10. The method of claim 7, wherein the metal layer is formed using an electroplating process.

11. The method of claim 7, wherein the mask pattern is removed using an organic solvent.

12. The method of claim 11, wherein the organic solvent comprises benzene, toluene, xylene, methyl acetate, ethyl acetate, butyl acetate, isobutyl acetate, pentyl acetate, isopentyl acetate, acetone, methylethylketone, methylbutylketone methylisobutylketone.

13. The method of claim 7, wherein the mask pattern and the portions of the seed layer and the metal layer disposed on the mask pattern are removed using water of about 70° C. to about 90° C.

14. The method of claim 7, wherein the mask pattern is formed of a tape having an adhesive property, and the portions of the seed layer and the metal layer disposed on the mask pattern are removed together with the mask pattern.

15. A method of manufacturing a printed circuit board comprising:
forming a first seed layer and a second seed layer on a base substrate, wherein the first seed layer is spaced apart from the second seed layer;
forming an active portion on the base substrate disposed between the first seed layer and the second seed layer, a portion of the first seed layer and a portion of the second seed layer;
selectively forming a metal layer on the first and second seed layers and the active portion; and
removing a portion of the metal layer disposed on the active pattern, thereby exposing the active pattern.

16. The method of claim 15, wherein the first and second seed layers are formed using a screen printing process.

17. The method of claim 15, wherein the active portion is formed by irradiating portions of the first and second seed layers and the base substrate disposed between the first seed layer and the second seed layer using a laser beam.

18. The method of claim 15, wherein forming the metal layer comprises
forming a first metal layer using an electroless plating process; and
forming a second metal layer on the first metal layer using an electroplating process.

19. The method of claim 15, wherein the portion of the metal layer formed on the active portion is removed using a tape having an adhesive property.

20. The method of claim 15, wherein the portion of the metal layer disposed on the active portion is removed by water of about 70° C. to about 90° C.
